(19) United States
(12) Patent Application Publication
(10) Pub. No.: US 2025/0364517 A1
(43) Pub. Date: Nov. 27, 2025

(54) SEMICONDUCTOR PACKAGE

(71) Applicant: Samsung Electronics Co., Ltd., Suwon-si (KR)

(72) Inventor: Jeon Il Lee, Suwon-si (KR)

(21) Appl. No.: 18/956,221

(22) Filed: Nov. 22, 2024

(30) Foreign Application Priority Data
May 22, 2024 (KR) 10-2024-0066555

(51) Int. Cl. H01L 25/18; H01L 23/00; H01L 23/31; H01L 23/48; H01L 23/498

(52) U.S. Cl. CPC H01L 25/18; H01L 23/3128; H01L 23/481; H01L 23/49827; H01L 24/16; H01L 24/24; H01L 24/32; H01L 24/73; H01L 2224/16146; H01L 2224/16235; H01L 2224/24225; H01L 2224/32235; H01L 2224/73204; H01L 2924/1431; H01L 2924/1436

(57) ABSTRACT

A semiconductor package may include a package substrate, a first interposer on the package substrate, a first semiconductor chip and a second semiconductor chip that are on the first interposer, a second interposer on the first semiconductor chip, a third semiconductor chip on the second interposer, and a first through via that extends into the first semiconductor chip and is between the first interposer and the second interposer.

### CROSS-REFERENCE TO RELATED APPLICATION

This application claims priority to and the benefit of Korean Patent Application No. 10-2024-0066555 filed in the Korean Intellectual Property Office on May 22, 2024, the entire contents of which is incorporated herein by reference.

### TECHNICAL FIELD

The present disclosure relates to a semiconductor package.

### BACKGROUND

The von Neumann structure operates such that memory stores data, and logic retrieves data from memory and performs operations. In this structure where the functions of memory and logic are separated, if the amount of logic calculations increases, it may take a lot of time to transmit data between memory and logic, which causes a bottleneck phenomenon. In particular, in fields where large-scale parallel calculations, such as artificial intelligence calculations, are performed or high-performance computing is desired, high-speed data transfer between memory and logic is desirable. Accordingly, package technology is developing to maximize the number of input/output (I/O) terminals between memory and logic and to reduce the wiring length between memory and logic.

### SUMMARY

The present disclosure provides a semiconductor package capable of high bandwidth communication between a logic chip, a first memory chip spaced apart in a horizontal direction from the logic chip, and a second memory chip spaced apart in a vertical direction from the logic chip.

A semiconductor package may include a package substrate, a first interposer on the package substrate, a first semiconductor chip and a second semiconductor chip that are on the first interposer, a second interposer on the first semiconductor chip, a third semiconductor chip on the second interposer, and a first through via that extends into the first semiconductor chip and is between the first interposer and the second interposer.

A semiconductor package may include a package substrate, a first interposer and a second interposer that are on an upper surface of the package substrate and are spaced apart from each other in a first direction that is perpendicular to an upper surface of the package substrate, a first semiconductor chip that is between an upper surface of the first interposer and a lower surface of the second interposer, a second semiconductor chip that is on the upper surface of the first interposer and is spaced apart from a side surface of the first semiconductor chip in a second direction that is parallel to the upper surface of the package substrate, a plurality of third semiconductor chips that are on an upper surface of the second interposer and are spaced apart from each other in the second direction, and a first through via that extends into the first semiconductor chip and is between the first interposer and the second interposer.

A semiconductor package may include a package substrate; an external connection member on a lower surface of the package substrate; a first interposer on an upper surface of the package substrate; a first interposer connection member that is between an upper surface of the package substrate and a lower surface of the first interposer; a first semiconductor chip and a second semiconductor chip that are on an upper surface of the first interposer and are spaced apart from each other in a first direction that is parallel to an upper surface of the package substrate; a first connection member that is between the upper surface of the first interposer and a lower surface of the first semiconductor chip; a second connection member that is between the upper surface of the first interposer and a lower surface of the second semiconductor chip; a second interposer on an upper surface of the first semiconductor chip; a second interposer connection member that is between an upper surface of the first semiconductor chip and a lower surface of the second interposer; a plurality of third semiconductor chips that are on an upper surface of the second interposer and are spaced apart from each other in the first direction; a third connection member that is between the upper surface of the second interposer and a lower surface of each of the plurality of third semiconductor chips; a molding member on the upper surface of the first interposer, the first interposer connection member, the first semiconductor chip, the second semiconductor chip, the first connection member, the second connection member, the second interposer, the second interposer connection member, the plurality of third semiconductor chips, and the third connection member; and a through via that extends into the first semiconductor chip and physically connects the first interposer and the second interposer.

According to some embodiments, high bandwidth communication between a logic chip, a first memory chip spaced apart in a horizontal direction from the logic chip, and a second memory chip spaced apart in a vertical direction from logic chip is available in the semiconductor package.

In addition, according to some embodiments, the size of the semiconductor package may be reduced, and the packaging process may be simplified.

### BRIEF DESCRIPTION OF THE DRAWINGS

FIG. 1 is a top plan view of a semiconductor package according to some embodiments.

FIG. 2 is a cross-sectional view of a semiconductor package according to some embodiments taken along line A-A′ of FIG. 1.

FIG. 3 is a top plan view of a semiconductor package according to some embodiments.

FIG. 4 is a cross-sectional view of a semiconductor package according to some embodiments taken along line A-A′ of FIG. 3.

FIG. 5 is a top plan view of a semiconductor package according to various embodiments.

FIG. 6 is a cross-sectional view of a semiconductor package according to some embodiments taken along line A-A′ of FIG. 5.

FIG. 7 is a cross-sectional view of a semiconductor package according to some embodiments taken along line A-A′ of FIG. 5.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions of the description may be omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. The term “connected” may be used herein to refer to a physical and/or electrical connection and may refer to a direct or indirect physical and/or electrical connection.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

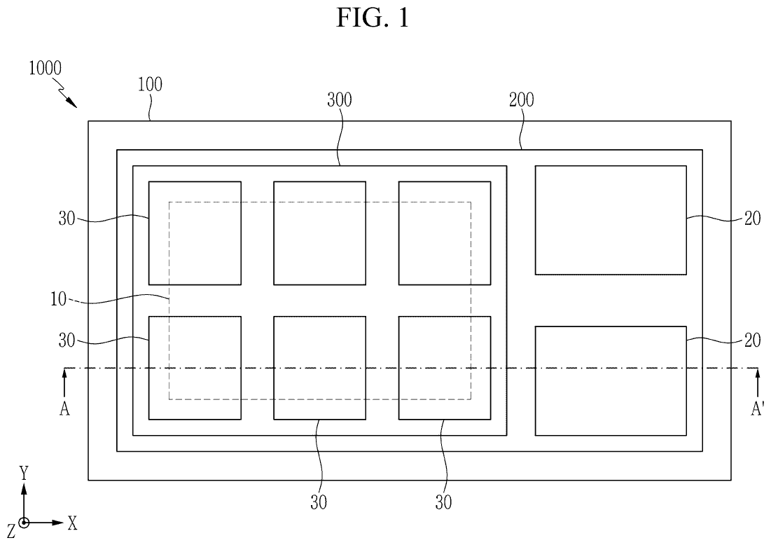

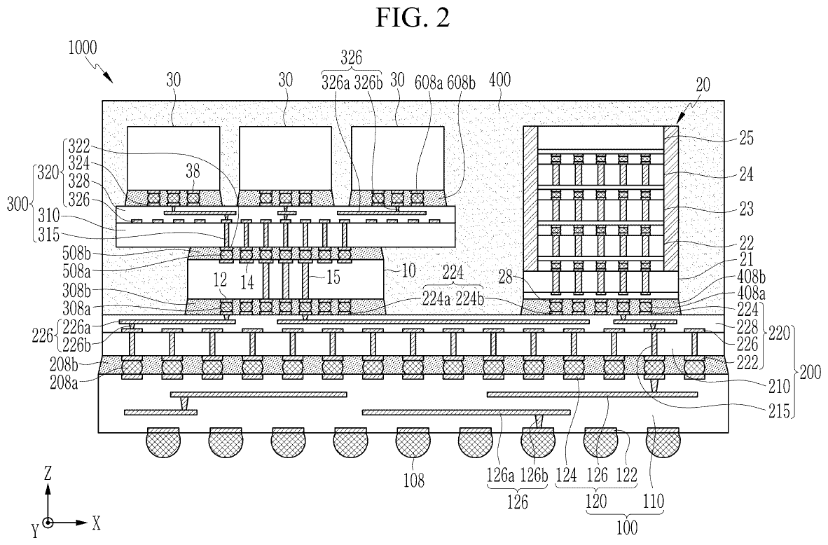

Hereinafter, referring to FIG. 1 and FIG. 2, a semiconductor package according to some embodiments will be described.

FIG. 1 is a top plan view of a semiconductor package according to some embodiments. FIG. 2 is a cross-sectional view of a semiconductor package according to some embodiments taken along line A-A′ of FIG. 1.

Referring to FIG. 1 and FIG. 2, a semiconductor package 1000 according to some embodiments may include a package substrate 100, a first interposer 200 disposed on the package substrate 100, a first semiconductor chip 10 and a second semiconductor chip 20 disposed on the first interposer 200, a second interposer 300 disposed on the first semiconductor chip 10, a third semiconductor chip 30 disposed on the second interposer 300, and a through via 15 penetrating or extending into the first semiconductor chip 10. The semiconductor package 1000 may be a 3.5D semiconductor package in which the first semiconductor chip 10 and the second semiconductor chip 20 are connected by the first interposer 200, and the first semiconductor chip 10 and the third semiconductor chip 30 are connected by the second interposer 300.

In addition to the above-described configuration, the semiconductor package 1000 may further include an external connection member 108, a first interposer connection member 208a, a second interposer connection member 508a, a first connection member 308a, a second connection member 408a, a third connection member 608a, and a molding member 400.

The first interposer 200 may be disposed on a first surface (e.g., upper surface) of the package substrate 100. The external connection member 108 may be disposed on a second surface (e.g., bottom surface) of the package substrate 100. The package substrate 100 may structurally support the first interposer 200. The package substrate 100 may be electrically connected to the first interposer 200 through the first interposer connection member 208a disposed on an upper surface of the package substrate 100. The package substrate 100 may be electrically connected to an external circuit or external device through the external connection member 108 disposed on a lower surface of the package substrate 100.

The package substrate 100 may include a plurality of wire layers 120 interposing or in a substrate insulation layer 110. The plurality of wire layers 120 may include a lower substrate pad 122 and an upper substrate pad 124 located on the lower surface and the upper surface of the package substrate 100, respectively, and a substrate internal wire 126 electrically connecting the lower substrate pad 122 and the upper substrate pad 124.

The external connection member 108 may be disposed on the lower substrate pad 122, and the first interposer connection member 208a may be disposed on the upper substrate pad 124. The substrate internal wire 126 may include a wiring 126a and a contact via 126b. The wiring 126a may planarly extend on the respective substrate insulation layers 110, and the contact via 126b may penetrate or extend into each substrate insulation layer 110 and connect the wiring 126a, the upper substrate pad 124, and/or the lower substrate pad 122.

For example, the package substrate 100 may be a printed circuit board (PCB). For example, the substrate insulation layer 110 may include a resin material (e.g., phenol resin, epoxy resin, or polyimide). For example, each of the plurality of wire layers 120 may include at least one of copper, aluminum, tungsten, nickel, gold, tin, manganese, cobalt, titanium, tantalum, ruthenium, or beryllium, or an alloy including the same. However, the embodiments are not limited thereto. The structure, shape, and/or material of the package substrate 100 may be changed in various ways.

For example, the external connection member 108 may have a ball shape. However, the embodiments are not limited thereto, and the shape of the external connection member 108 may be changed in various ways. As another example, the external connection member 108 may have a land or pin shape.

For example, the external connection member 108 may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the external connection member 108 may include tin or include an alloy including tin (e.g., Sn—Ag—Cu alloy). However, the embodiments are not limited thereto, and the material of the external connection member 108 may be changed in various ways.

The first semiconductor chip 10 and the second semiconductor chip 20 may be mounted on the first interposer 200, and the first interposer 200 may be disposed on the package substrate 100. The first surface (e.g., bottom surface) of the first interposer connection member 208a may be disposed on the first interposer 200. The first semiconductor chip 10 and the second semiconductor chip 20 may be disposed on the second surface (e.g., upper surface) of the first interposer 200.

The first interposer 200 may have a fine (or relatively smaller) pitch or a fine (or relatively smaller) pattern that is finer or smaller than the package substrate 100. By using the first interposer 200 having the fine pitch or fine pattern, the first semiconductor chip 10 and the second semiconductor chip 20 may be electrically connected to the package substrate 100, and the first semiconductor chip 10 and the second semiconductor chip 20 may be electrically connected.

In some embodiments, the first interposer 200 may include a first interposer substrate 210, a plurality of first interposer-through vias 215, and a first wiring portion 220. Each of the plurality of first interposer-through vias 215 may penetrate or extend into the first interposer substrate 210. The first wiring portion 220 may be disposed on the first interposer substrate 210.

The first wiring portion 220 may include a first lower pad 222 and a first upper pad 224 located on the first surface (e.g., bottom surface) and the second surface (e.g., upper surface) of the first interposer 200, respectively, a first wire insulation layer 228 disposed on the first interposer substrate 210, and a first interposer wiring 226 interposing or in the first wire insulation layer 228. The first interposer wiring 226 may include a first wiring 226a and a first contact via 226b.

The first wiring portion 220 and the plurality of first interposer-through vias 215 of the first interposer 200 may be connected to form a desired circuit pattern. The first wiring portion 220 and the plurality of first interposer-through vias 215 may perform various functions depending on the design. The first wiring portion 220 and the plurality of first interposer-through vias 215 form a ground pattern, a power pattern, and/or a signal pattern. The signal pattern may be various signals excluding the signals applied to the ground pattern, power pattern, or the like, for example, a circuit pattern for data transfer. The first contact via 226b included in the first wiring portion 220 may include a ground contact via, a power contact via, and/or a signal contact via. The plurality of first interposer-through vias 215 may include a ground through via, a power through via, and a signal through via.

For example, the first interposer substrate 210 may include a semiconductor material (e.g., silicon). In some embodiments, the first interposer substrate 210 may be a silicon substrate. When the first interposer substrate 210 is a silicon substrate, the first interposer-through via 215 penetrating or extending into the first interposer substrate 210 may be a through-silicon via (TSV). When the first interposer substrate 210 is a silicon substrate, the wire insulation layer (the first wire insulation layer 228) of the first wiring portion 220 disposed on the first interposer substrate 210 may include a silicon compound.

However, without being limited to the above-described example, the material of the first interposer substrate 210 may be changed in various ways. As another example, the first interposer substrate 210 may include an insulating material, glass, or ceramic. For example, the first interposer substrate 210 may include an organic insulating material (e.g., photosensitivity insulating material). In some embodiments, the first interposer substrate 210 may include an organic insulation layer and a redistribution layer interposing or in the organic insulation layer (e.g., photosensitivity insulating material layer). In this case, the first wiring portion 220 may form a redistribution substrate or a redistribution portion, together with the redistribution layer of the first interposer substrate 210.

The first interposer connection member 208a connecting the first interposer 200 and the package substrate 100 may be disposed on the first lower pad 222. The first upper pad 224 may include a first pad 224a and a second pad 224b. A first connection member 308a connecting the first interposer 200 and the first semiconductor chip 10 may be disposed on the first pad 224a. The second connection member 408a connecting the first interposer 200 and the second semiconductor chip 20 may be disposed on the second pad 224b.

The first pad 224a may be disposed on an upper surface of the first interposer 200 overlapping at least a portion of the first semiconductor chip 10 in the Z direction, which is perpendicular to an upper surface of the package substrate 100. The second pad 224b may be disposed on the upper surface of the first interposer 200 overlapping at least a portion of the second semiconductor chip 20 in the Z direction. For example, a plurality of first pads 224a and a plurality of second pads 224b may be disposed to be spaced apart by a preset interval along a X direction, which is parallel to an upper surface of the package substrate 100. Although not shown, the plurality of first pads 224a and the plurality of second pads 224b may be disposed to be spaced apart by a preset interval along a Y direction. For example, the Y direction may be a direction crossing or intersecting the X direction, e.g., orthogonally, and the Y direction may be parallel to the upper surface of the package substrate 100.

In some embodiments, the first wire insulation layer 228 and the first interposer wiring 226 may be disposed on an upper surface of the first interposer substrate 210. However, the embodiments are not limited thereto. The first wire insulation layer 228 and the first interposer wiring 226 may be further disposed on a lower surface of the first interposer substrate 210. FIG. 2 only illustrates an upper wire layer located in an upper portion of the first interposer substrate 210, but a lower wire layer may be further located in a lower portion of the first interposer substrate 210.

The first interposer wiring 226 may include the first wiring 226a and the first contact via 226b. The first wiring 226a may planarly extend on the respective first wire insulation layers 228, and the first contact via 226b may penetrate or extend into each first wire insulation layer 228. The first wiring 226a may be connected to the first lower pad 222, the first upper pad 224, and/or the first interposer-through via 215, directly or through the first contact via 226b. For example, the first wiring 226a directly connected to the first interposer-through via 215 may have a pad shape. The first contact via 226b may connect the first lower pad 222, the first upper pad 224, the first wiring 226a, and/or the first interposer-through via 215.

The first interposer-through via 215 may penetrate or extend into the first interposer substrate 210 and connect the first upper pad 224 and the first lower pad 222. In some embodiments, the first interposer-through via 215 may connect an upper wire layer located in the upper portion of the first interposer substrate 210 and a lower wire layer located in the lower portion of the first interposer substrate 210.

The first wiring portion 220 and the plurality of first interposer-through vias 215 may include a vertical connection wiring electrically connecting the first upper pad 224 and the first lower pad 222, and a horizontal connection wiring electrically connecting the first pad 224a and the second pad 224b. By the vertical connection wiring, the first interposer 200 may electrically connect the first semiconductor chip 10 and the second semiconductor chip 20 to the package substrate 100. By the horizontal connection wiring, the first interposer 200 may electrically connect the first semiconductor chip 10 and the second semiconductor chip 20 to each other.

Each of the first lower pad 222, the first upper pad 224, a first interposer wiring 226, and the first interposer-through via 215 of the first interposer 200 may include various conductive materials. The first lower pad 222, the first upper pad 224, and the first interposer wiring 226, and the first interposer-through via 215 may be formed of different materials, or at least two of the first lower pad 222, the first upper pad 224, the first interposer wiring 226, or the first interposer-through via 215 may be formed of the same material. The first lower pad 222, the first upper pad 224, the first interposer wiring 226, and/or the first interposer-through via 215 may be formed in a single layer or multiple layers. For example, each of the first lower pad 222, the first upper pad 224, the first interposer wiring 226, and the first interposer-through via 215 may include at least one of copper, aluminum, tungsten, nickel, gold, tin, manganese, cobalt, titanium, tantalum, ruthenium, or beryllium, or an alloy including the same.

The first wire insulation layer 228 and the first interposer substrate 210 of the first interposer 200 may include various insulating materials capable of insulating the pad, wiring, and/or via among the first lower pad 222, the first upper pad 224, the first interposer wiring 226, and the first interposer-through via 215, which may not be connected.

The first interposer connection member 208a may be located on the first lower pad 222 and on a lower surface of the first interposer 200. The first interposer connection member 208a may be located on the upper substrate pad 124 and on the upper surface of the package substrate 100. The first interposer connection member 208a may be located between the first lower pad 222 of the first interposer 200 and the upper substrate pad 124 of the package substrate 100. The first interposer connection member 208a may electrically connect the first interposer 200 and the package substrate 100. A first interposer underfill layer 208b may be further provided around the first interposer connection member 208a between the first interposer 200 and the package substrate 100. The first interposer underfill layer 208b may fill at least a portion of or be in the space between the first interposer 200 and the package substrate 100. The first interposer connection member 208a, the first lower pad 222, and the upper substrate pad 124 may be surrounded by at least a portion of the first interposer underfill layer 208b.

For example, the first interposer connection member 208a may have a ball shape. However, the embodiments are not limited thereto, and the shape of the first interposer connection member 208a may be changed in various ways. As another example, the first interposer connection member 208a may have a land or pin shape.

For example, the first interposer connection member 208a may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, the first interposer connection member 208a may include tin or include an alloy including tin (e.g., Sn—Ag—Cu alloy). However, the embodiments are not limited thereto, and the material of the first interposer connection member 208a may be changed in various ways.

The first interposer underfill layer 208b may include a thermosetting resin such as an epoxy resin, a thermoplastic resin such as polyimide, a resin including an inorganic filler and/or a glass fiber, or an epoxy molding compound (EMC). The first interposer underfill layer 208b is not limited to what is described above or illustrated in the drawings, and its material or shape may be changed in various ways.

According to the above-described embodiment, the package substrate 100 and the first interposer 200 may be separately provided such that they may be connected to each other by the first interposer connection member 208a. However, the embodiments are not limited thereto. According to some embodiments, a substrate in which the package substrate 100 and the first interposer 200 are integrated may be used. For example, instead of the package substrate 100 and the first interposer 200, a glass package substrate may be used. In addition, it may be changed in various ways.

Referring to FIG. 1, in a plan view, the size or area of the package substrate 100 is larger than the size or area of the first interposer 200, thereby enabling the package substrate to have structural stability. However, the embodiments are not limited thereto, and may be changed in various ways.

The first semiconductor chip 10 and the second semiconductor chip 20 may be disposed on the upper surface of the first interposer 200 to be spaced apart in a horizontal direction. The first semiconductor chip 10 and the second semiconductor chip 20 may be disposed to be spaced apart in a direction parallel to the upper surface of the first interposer 200. For example, the first semiconductor chip 10 and the second semiconductor chip 20 may be disposed to be spaced apart in the X direction.

In some embodiments, the first semiconductor chip 10 may be a logic chip. Here, the logic chip may be a controller configured to control the memory chip. For example, the first semiconductor chip 10 may be an application-specific integrated circuit (ASIC) as a host, such as a central processing unit (CPU), a graphics processing unit (GPU), a neural processing unit (NPU) system-on-chip (SOC), or an application processor.

A first chip lower pad 12 may be disposed on the first surface (e.g., bottom surface) of the first semiconductor chip 10 adjacent to the first interposer 200. For example, a plurality of first chip lower pads 12 may be disposed to be spaced apart by a preset interval along the X direction. Although not shown, the plurality of first chip lower pads 12 may be disposed to be spaced apart by a preset interval along the Y direction. The first connection member 308a may be disposed on the first chip lower pad 12. The first connection member 308a may be located between the first chip lower pad 12 and the first pad 224a of the first interposer 200. The first interposer 200 and the first semiconductor chip 10 may be connected through the first connection member 308a. A first underfill layer 308b may be further provided around the first connection member 308a between the first interposer 200 and the first semiconductor chip 10. The first underfill layer 308b may fill at least a portion of or be in the space between the first interposer 200 and the first semiconductor chip 10. The first connection member 308a, the first chip lower pad 12, and the first pad 224a may be surrounded by at least a portion of the first underfill layer 308b.

In some embodiments, the second semiconductor chip 20 may be a memory chip. For example, the second semiconductor chip 20 may be a stacked memory chip. The second semiconductor chip 20 may include a plurality of memory chips stacked in a Z direction perpendicular to the upper surface of the first interposer 200. The second semiconductor chip 20 includes the plurality of memory chips that provide a relatively short delay time and high bandwidth, and may be referred to as a high bandwidth memory (HBM).

For example, the second semiconductor chip 20 may include one buffer die 21 and a plurality of core dies 22, 23, 24, and 25. The buffer die 21 may be located in a lowermost portion of the second semiconductor chip 20. The plurality of core dies 22, 23, 24, and 25 may be stacked on the buffer die 21. The buffer die 21 and the plurality of core dies 22, 23, 24, and 25 stacked as such may be electrically connected through a silicon penetration electrode.

The buffer die 21 may be a logic chip. The buffer die 21 may include a circuit connected to the first semiconductor chip 10 and configured to control an overall operation of the second semiconductor chip 20. Each of the plurality of core dies 22, 23, 24, and 25 may be a memory chip. For example, each of the plurality of core dies 22, 23, 24, and 25 may be a dynamic random-access memory (DRAM), but is not limited thereto. Each of the plurality of core dies 22, 23, 24, and 25 may be changed to various memories.

FIG. 2 illustrates that the second semiconductor chip 20 is provided with one buffer die and four core dies, but the number of the buffer dies and the core dies is not limited thereto. According to some embodiments, the second semiconductor chip 20 may have a buffer-less structure that does not include the buffer die 21. According to the buffer-less structure, the resistance, power consumption amount, and latency of the second semiconductor chip 20 may be reduced. Various other structures may be applied to the second semiconductor chip 20.

A second chip lower pad 28 may be disposed on the first surface (e.g., bottom surface) of the second semiconductor chip 20 adjacent to the first interposer 200. For example, a plurality of second chip lower pads 28 may be disposed to be spaced apart by a preset interval along the X direction. Although not shown, the plurality of second chip lower pads 28 may be disposed to be spaced apart by a preset interval along the Y direction. The second connection member 408a may be disposed on the second chip lower pad 28. The second connection member 408a may be located between the second chip lower pad 28 and the second pad 224b of the first interposer 200. The first interposer 200 and the second semiconductor chip 20 may be connected through the second connection member 408a. A second underfill layer 408b may be further provided around the second connection member 408a between the first interposer 200 and the second semiconductor chip 20. The second underfill layer 408b may fill at least a portion of or be in the space between the first interposer 200 and the second semiconductor chip 20. The second connection member 408a, the second chip lower pad 28, and the second pad 224b may be surrounded by at least a portion of the second underfill layer 408b.

For example, each of the first connection member 308a and the second connection member 408a may have a ball shape. However, the embodiments are not limited thereto, and the shape of the first connection member 308a and the second connection member 408a may be changed in various ways. As another example, each of the first connection member 308a and the second connection member 408a may have a land or pin shape.

For example, each of the first connection member 308a and the second connection member 408a may include at least one of tin, lead, bismuth, silver, copper, aluminum, tungsten, nickel, manganese, cobalt, titanium, tantalum, ruthenium, beryllium, indium, molybdenum, magnesium, rhenium, or gallium, or an alloy including the same. For example, each of the first connection member 308a and the second connection member 408a may include tin or include an alloy including tin (e.g., Sn—Ag—Cu alloy). However, the embodiments are not limited thereto, and the material of each of the first connection member 308a and the second connection member 408a may be changed in various ways.

For example, each of the first underfill layer 308b and the second underfill layer 408b may include a thermosetting resin such as an epoxy resin, a thermoplastic resin such as polyimide, a resin including an inorganic filler and/or a glass fiber, or an epoxy molding compound (EMC).

FIG. 2 illustrates that the first underfill layer 308b is located between the first semiconductor chip 10 and the first interposer 200, and the second underfill layer 408b is located between the second semiconductor chip 20 and the first interposer 200, but it is not limited thereto. The first semiconductor chip 10 and the second semiconductor chip 20 may be connected to the first interposer 200 by one underfill layer located between the first semiconductor chip 10 and the second semiconductor chip 20 and the first interposer 200. Each of the first underfill layer 308b and the second underfill layer 408b is not limited to what is described above or illustrated in the drawings, and its material or shape may be changed in various ways.

Referring to FIG. 1, a plurality of second semiconductor chips 20 may be disposed on the first interposer 200. Each of the plurality of second semiconductor chips 20 may be connected to the first semiconductor chip 10 through the first interposer 200.

Referring to FIG. 2, a plurality of third semiconductor chips 30 may be mounted on the second interposer 300, and the second interposer 300 may be disposed on the first semiconductor chip 10. The second interposer 300 may be located between the plurality of third semiconductor chips 30 and the first semiconductor chip 10. The plurality of third semiconductor chips 30 may be spaced apart from the first semiconductor chip 10 in the Z direction perpendicular to the upper surface of the first interposer 200. The second interposer connection member 508a may be disposed on the first surface (e.g., bottom surface) of the second interposer 300. The plurality of third semiconductor chips 30 may be disposed on the second surface (e.g., upper surface) of the second interposer 300.

Referring to FIG. 1, the second interposer 300 may overlap at least a portion of the first semiconductor chip 10 in the Z direction and/or in a plan view. The second interposer 300 may be spaced apart from the second semiconductor chip 20 in the X direction and/or in a plan view. The second interposer 300 may overlap at least a portion of the plurality of third semiconductor chips 30 in the Z direction and/or in a plan view. In a plan view, the size or area of the second interposer 300 may be greater than a sum of the size or area of the plurality of third semiconductor chips 30. In a plan view, the size or area of the second interposer 300 may be greater than the size or area of the first semiconductor chip 10. However, the embodiments are not limited thereto, and may be changed in various ways.

The plurality of third semiconductor chips 30 may be disposed on an upper surface of the second interposer 300, to be spaced apart in the horizontal direction. The plurality of third semiconductor chips 30 may be disposed to be spaced apart in a direction parallel to the upper surface of the second interposer 300. For example, the plurality of third semiconductor chips 30 may be disposed to be spaced apart from each other in the X direction and the Y direction. For example, the plurality of third semiconductor chips 30 may be disposed in a matrix format, but is not limited thereto, and their arrangement form may be changed in various ways.

The second interposer 300 may have a fine (or smaller) pitch or a fine (or smaller) pattern, and by using the second interposer 300, the plurality of third semiconductor chips 30 may be electrically connected to the first semiconductor chip 10, and the plurality of third semiconductor chips 30 may be electrically connected to each other.

In some embodiments, the second interposer 300 may include a second interposer substrate 310, a plurality of second interposer-through vias 315, and a second wiring portion 320. Each of the plurality of second interposer-through vias 315 may penetrate or extend into the second interposer substrate 310. The second wiring portion 320 may be disposed on the second interposer substrate 310.

The second wiring portion 320 may include a second lower pad 322 and a second upper pad 324 located on the first surface (e.g., bottom surface) and the second surface (e.g., upper surface) of the second interposer 300, respectively, a second wire insulation layer 328 disposed on the second interposer substrate 310, and a second interposer wiring 326 interposing or in the second wire insulation layer 328. The second interposer wiring 326 may include a second wiring 326a and a second contact via 326b.

As for the second interposer 300, the description with respect to the first interposer 200 may be applied in the same or similar way. The second interposer substrate 310, the second interposer-through via 315, and the second wiring portion 320 of the second interposer 300 may correspond to the first interposer substrate 210, the first interposer-through via 215, and the first wiring portion 220 of the first interposer 200, respectively. Hereinafter, regarding the configurations of the second interposer 300, redundant description is not included herein and differences will be focused.

The second lower pad 322 may be disposed on a lower surface of the second interposer 300 overlapping at least a portion of the first semiconductor chip 10 in the Z direction. The second upper pad 324 may be disposed on the upper surface of the second interposer 300 overlapping at least a portion of the third semiconductor chip 30 in the Z direction.

The second interposer connection member 508a connecting the second interposer 300 and the first semiconductor chip 10 may be disposed on the second lower pad 322. The second interposer connection member 508a may connect an upper surface of the first semiconductor chip 10 and the lower surface of the second interposer 300. The second interposer connection member 508a may be disposed on a first chip upper pad 14 and on the upper surface of the first semiconductor chip 10. The second interposer connection member 508a may be located between the second lower pad 322 of the second interposer 300 and the first chip upper pad 14 of the first semiconductor chip 10. The second interposer 300 and the first semiconductor chip 10 may be electrically connected by the second interposer connection member 508a. A second interposer underfill layer 508b may be further provided around the second interposer connection member 508a between the second interposer 300 and the first semiconductor chip 10. The second interposer underfill layer 508b may fill at least a portion of or be in the space between the second interposer 300 and the first semiconductor chip 10. The second interposer connection member 508a, the second lower pad 322, and the first chip upper pad 14 may be surrounded by at least a portion of the second interposer underfill layer 508b.

The third connection member 608a connecting the second interposer 300 and the third semiconductor chip 30 may be disposed on the second upper pad 324. The third connection member 608a may connect the upper surface of the second interposer 300 and a lower surface of each of the plurality of third semiconductor chips 30. The third connection member 608a may be disposed on a third chip lower pad 38 and on a lower surface of the third semiconductor chip 30. The third connection member 608a may be located between the second upper pad 324 of the second interposer 300 and the third chip lower pad 38 of the third semiconductor chip 30. The second interposer 300 and the third semiconductor chip 30 may be electrically connected by the third connection member 608a. A third underfill layer 608b may be further provided around the third connection member 608a between the second interposer 300 and the third semiconductor chip 30. The third underfill layer 608b may fill at least a portion of or be in the space between the second interposer 300 and the third semiconductor chip 30. The third connection member 608a, the third chip lower pad 38, and the second upper pad 324 may be surrounded by at least a portion of the third underfill layer 608b.

FIG. 2 illustrates that a plurality of third underfill layers 608b are located between the plurality of third semiconductor chips 30 and the second interposer 300, respectively, but is not limited thereto. The plurality of third underfill layers 608b may be integrally formed. That is, by a single underfill layer located between the plurality of third semiconductor chips 30 and the second interposer 300, the plurality of third semiconductor chips 30 may be connected to the second interposer 300.

The second interposer-through via 315 may penetrate or extend into the second interposer substrate 310 and connect the second upper pad 324 and the second lower pad 322. In some embodiments, the second interposer-through via 315 may include an upper wire layer located in an upper portion of the second interposer substrate 310 and a lower wire layer located in a lower portion of the second interposer substrate 310.

The second interposer 300 may include a vertical connection wiring and a horizontal connection wiring. A portion of the second wiring portion 320 and the second interposer-through via 315 may configure the vertical connection wiring, and another portion of the second wiring portion 320 may configure the horizontal connection wiring. By the vertical connection wiring of the second interposer 300, the plurality of third semiconductor chips 30 may be electrically connected to the first semiconductor chip 10. By the horizontal connection wiring of the second interposer 300, the plurality of third semiconductor chips 30 may be electrically connected.

In some embodiments, the third semiconductor chip 30 may be a memory chip. For example, each of the plurality of third semiconductor chips 30 may be a processing-in-memory (PIM), which may be a memory device that includes a DRAM, HBM, or operation unit. However, the embodiments are not limited thereto, and each of the plurality of third semiconductor chips 30 may be changed to various memory devices.

According to what is described above, the first semiconductor chip 10 may be a logic chip. The first semiconductor chip 10 may be electrically connected to the second semiconductor chip 20 and the plurality of third semiconductor chips 30 through the first interposer 200 and the second interposer 300. The first semiconductor chip 10 may control the second semiconductor chip 20 and the plurality of third semiconductor chips 30. For example, the first semiconductor chip 10 may read data stored in the second semiconductor chip 20, and may write it in each of the plurality of third semiconductor chips 30 or over the plurality of third semiconductor chips 30. As another example, the first semiconductor chip 10 may read data stored in each of the plurality of third semiconductor chips 30, and write it in the second semiconductor chip 20.

The first semiconductor chip 10 may be electrically connected to each of the plurality of third semiconductor chips 30 through the second interposer 300. The first semiconductor chip 10 may control each of the plurality of third semiconductor chips 30. For example, the first semiconductor chip 10 may read data stored in one third semiconductor chip 30 among the plurality of third semiconductor chips 30, and write it in another third semiconductor chip 30. For example, when the third semiconductor chip 30 is a PIM, the data read from or written in the third semiconductor chip 30 may be a result calculated by an operation unit located within the third semiconductor chip 30.

For example, a data input/output wiring between the plurality of third semiconductor chips 30 may be connected through the second interposer 300. For example, as the first semiconductor chip 10 may control each third semiconductor chip 30 to transfer data stored in one third semiconductor chip 30 among the plurality of third semiconductor chips 30 or the result calculated based on the stored data to another third semiconductor chip 30, the third semiconductor chips 30 may directly exchange data without passing through the first semiconductor chip 10. At this time, the third semiconductor chips 30 may receive a control signal including a clock signal, an address, and/or a command for exchanging data from the first semiconductor chip 10.

In some embodiments, the through via 15 may penetrate or extend into the first semiconductor chip 10. The through via 15 may connect the first chip lower pad 12 and the first chip upper pad 14. According to what is described above, the first chip lower pad 12 may be connected to the first interposer 200, and the first chip upper pad 14 may be connected to the second interposer 300. The through via 15 may penetrate or extend into the first semiconductor chip 10 and connect the first interposer 200 and the second interposer 300. By the through via 15, the length of wiring through which the plurality of third semiconductor chips 30 are connected to the first semiconductor chip 10, the second semiconductor chip 20, and/or the package substrate 100 may be shortened.

Since the first semiconductor chip 10 includes various circuits and wirings, the through via 15 may penetrate or extend into a region in which the circuit and wiring is not formed within the first semiconductor chip 10. FIG. 2 illustrates that a penetration region of the through via 15 is located in a central portion of the first semiconductor chip 10, but it is not limited thereto. The penetration region of the through via 15 may be located in an edge portion of the first semiconductor chip 10.

For example, the area of the region in which the circuit and wiring is not formed within the first semiconductor chip 10 may be small to accommodate the desired number of the through vias 15. In this case, a portion of a plurality of through vias 15 may be located in a first region, and another portion thereof may be located in a second region. The first region and the second region may be spaced apart from each other in the horizontal direction (the X direction and/or the Y direction).

When the first semiconductor chip 10 is a silicon chip, the through via 15 penetrating or extending into the first semiconductor chip 10 may be a through-silicon via. The through via 15 may have a pillar shape. The planar shape of the through via 15 may be a circle or a polygon such as a quadrangle. The through via 15 may be formed as a single layer or multiple layers.

The through via 15 may include a various conductive material. For example, the through via 15 may include at least one of copper, aluminum, tungsten, nickel, gold, tin, manganese, cobalt, titanium, tantalum, ruthenium, or beryllium, or an alloy including the same. However, the embodiments are not limited thereto, and the shape, structure, and/or material of the through via 15 may be changed in various ways.

The molding member 400 surrounding at least a portion of the first interposer 200, the first semiconductor chip 10, the second semiconductor chip 20, the second interposer 300, and the plurality of third semiconductor chips 30 may be provided on the package substrate 100. The molding member 400 may surround at least a portion of the first interposer connection member 208a, the first connection member 308a, the second connection member 408a, the second interposer connection member 508a, and the third connection member 608a.

For example, the molding member 400 may cover or overlap at least a portion of the upper surface of the first interposer 200 and the upper surface of the second interposer 300 in the Z direction. For example, the molding member 400 may further cover or overlap at least a portion of the second semiconductor chip 20 and an upper surface of the third semiconductor chip 30 in the Z direction. The molding member 400 may entirely cover or overlap side surfaces of the first semiconductor chip 10, the second semiconductor chip 20, and the third semiconductor chip 30 in the X direction and/or Y direction, and may entirely fill or be in the space between the first semiconductor chip 10 and the second semiconductor chip 20, the space between the second semiconductor chip 20 and the third semiconductor chip 30, and the space between the plurality of third semiconductor chips 30.

For example, the molding member 400 may include a thermosetting resin such as an epoxy resin, a thermoplastic resin such as polyimide, a resin including an inorganic filler and/or a glass fiber, or an epoxy molding compound. However, the embodiments are not limited thereto, and the shape and/or material of the molding member 400 may be changed in various ways.

In the above-described embodiments, a first chip and a second chip, a chip and an interposer, and/or an interposer and a substrate are connected through connection members (e.g., the first interposer connection member 208a, the first connection member 308a, the second connection member 408a, the second interposer connection member 508a, and/or the third connection member 608a), but the embodiments are not limited thereto. According to some embodiments, an upper portion pad of one configuration and a lower portion pad of another configuration may be directly conjoined and connected without a connection member. When the conjoined pads are copper pads, the above-described connection method may be referred to as hybrid copper bonding (HCB).

The semiconductor package 1000 according to some embodiments may include the first interposer 200 connecting the first semiconductor chip 10 and the second semiconductor chip 20 spaced apart in a direction parallel to the upper surface of the package substrate 100 and the second interposer 300 connecting the first semiconductor chip 10 and the plurality of third semiconductor chips 30 spaced apart in the Z direction perpendicular to the upper surface of the package substrate 100, and may include the through via 15 configured to penetrate or extend into the first semiconductor chip 10 and connect the first interposer 200 and the second interposer 300. The second interposer 300 may be connected to the upper surface of the first semiconductor chip 10 and may be on the upper surface of the first semiconductor chip 10, and the plurality of third semiconductor chips 30 may be spaced apart from and connected to each other in the direction parallel to the upper surface of the second interposer 300.

According to some embodiments, compared to the comparative example in which the third semiconductor chip 30 is directly connected on the upper surface of the first semiconductor chip 10, the number of the third semiconductor chips 30 that can be connected to the first semiconductor chip 10 may increase, and the number of I/O terminals of each of the first semiconductor chip 10 and the third semiconductor chip 30 may be increased. According to some embodiments, high bandwidth communication between the plurality of third semiconductor chips 30, the first semiconductor chip 10, and the second semiconductor chip 20 may be possible.

According to some embodiments, compared to the comparative example in which the first interposer 200 and the second interposer 300 are connected through the via penetrating or extending into the molding member 400 outside the first semiconductor chip 10, the size of the semiconductor package 1000 may decrease, and the packaging process may be simplified.

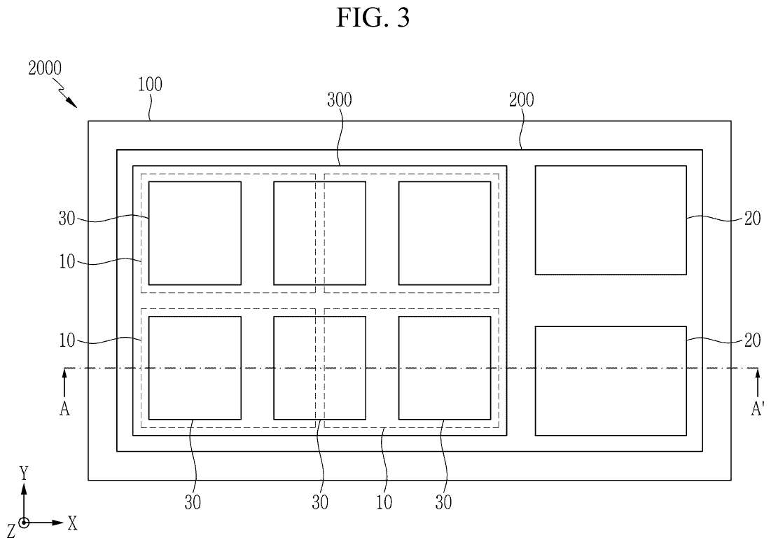

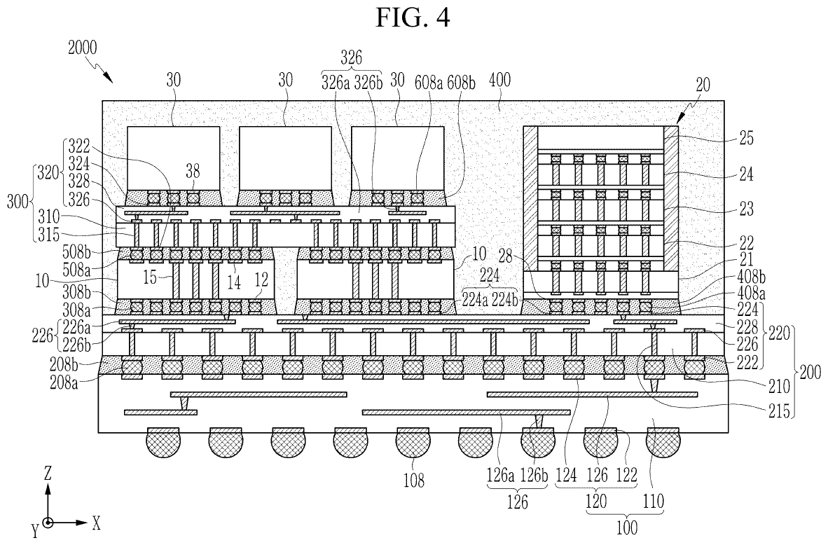

Hereinafter, referring to FIG. 3 and FIG. 4, a semiconductor package according to some embodiments will be described.

FIG. 3 is a top plan view of a semiconductor package 2000 according to some embodiments. FIG. 4 is a cross-sectional view of a semiconductor package according to some embodiments taken along line A-A′ of FIG. 3. Hereinafter, as for the FIG. 3 and configurations in FIG. 4 referred to by the same reference symbol as the configurations of the semiconductor package 1000 of FIG. 1 and FIG. 2, the description described above with reference to FIG. 1 and FIG. 2 may be applied in the same or similar way. Therefore, redundant description may be omitted or simplified, and the semiconductor package 2000 of FIG. 3 and FIG. 4 will be described focusing on differences from the semiconductor package 1000 of FIG. 1 and FIG. 2.

According to some embodiments shown in FIG. 3 and FIG. 4, the semiconductor package 2000 may include a plurality of first semiconductor chips 10. The plurality of first semiconductor chips 10 may be disposed to be spaced apart from each other in the direction parallel to the upper surface of the package substrate 100. For example, the plurality of first semiconductor chips 10 may be disposed to be spaced apart in the X direction and the Y direction. The plurality of first semiconductor chips 10 may be disposed in a matrix format. Each of the plurality of first semiconductor chips 10 may overlap with at least one third semiconductor chip 30, in a plan view. However, the embodiments are not limited thereto, and their arrangement form may be changed in various ways. FIG. 3 illustrates four first semiconductor chips 10, but it is not limited thereto, and the number of the first semiconductor chip 10 may be changed in various ways.

In some embodiments, the plurality of first semiconductor chips 10 may be disposed between the first interposer 200 and the second interposer 300. Each of the plurality of first semiconductor chips 10 may be connected to the first interposer 200 and the second interposer 300, respectively. The first chip lower pad 12 may be disposed on a lower surface of each of the plurality of first semiconductor chips 10, and the first chip upper pad 14 may be disposed on an upper surface of each of the plurality of first semiconductor chips 10. The first chip lower pad 12 may be connected to the first upper pad 224 (e.g., the first pad 224a) of the first interposer 200 by the first connection member 308a. The first chip upper pad 14 may be connected to the second lower pad 322 of the second interposer 300 by the second interposer connection member 508a.

Each of the plurality of first semiconductor chips 10 may be electrically connected to the second semiconductor chip 20 through the first interposer 200. For example, the plurality of second semiconductor chips 20 may be connected to the first interposer 200. Each of the plurality of first semiconductor chips 10 may be electrically connected to at least one of the plurality of second semiconductor chips 20. The plurality of first semiconductor chips 10 may be connected to the same second semiconductor chip 20, respectively, and the plurality of first semiconductor chips 10 may be connected to a different the second semiconductor chip 20, respectively.

In some embodiments, each of the plurality of first semiconductor chips 10 may be a logic chip. Each of the plurality of second semiconductor chips 20 may be a memory chip (e.g., HBM). The first semiconductor chip 10 may control the second semiconductor chip 20 connected to the first semiconductor chip 10. Each of the plurality of second semiconductor chips 20 may be electrically connected to at least one of the plurality of first semiconductor chips 10.

Each of the plurality of first semiconductor chips 10 may be electrically connected to the third semiconductor chip 30 through the second interposer 300. In some embodiments, the plurality of third semiconductor chips 30 may be connected to the second interposer 300, respectively. Each of the plurality of first semiconductor chips 10 may be electrically connected to at least one of the plurality of third semiconductor chips 30. The plurality of first semiconductor chips 10 may be connected to the same third semiconductor chip 30, respectively, and the plurality of first semiconductor chips 10 may be connected to a different the third semiconductor chip 30, respectively.

According to what is described above, each of the plurality of first semiconductor chips 10 may be a logic chip. Each of the plurality of third semiconductor chips 30 may be a memory chip (e.g., DRAM, HBM, PIM). The first semiconductor chip 10 may control the third semiconductor chip 30 connected to the first semiconductor chip 10. Each of the plurality of third semiconductor chips 30 may be electrically connected to at least one of the plurality of first semiconductor chips 10.

In the above-described embodiments, each of the plurality of first semiconductor chips 10 is connected to at least one second semiconductor chip 20 and the at least one third semiconductor chip 30, but the embodiments are not limited thereto. According to some embodiments, a portion of the plurality of first semiconductor chips 10 may be connected to the second semiconductor chip 20 but may not be connected to the third semiconductor chip 30. Another portion of the plurality of first semiconductor chips 10 may be connected to the third semiconductor chip 30 but may not be connected to the second semiconductor chip 20.

In some embodiments, the through via 15 may penetrate or extend into each of the plurality of first semiconductor chips 10. The through via 15 may connect the first chip lower pad 12 and the first chip upper pad 14 of each of the plurality of first semiconductor chips 10. According to what is described above, the first chip lower pad 12 may be connected to the first interposer 200, and the first chip upper pad 14 may be connected to the second interposer 300. The through via 15 penetrating or extending into each of the plurality of first semiconductor chips 10 may connect the first interposer 200 and the second interposer 300. By the through via 15, the signal transmission path between the plurality of third semiconductor chips 30 and the first semiconductor chip 10, the second semiconductor chip 20, and/or the package substrate 100 may be optimized.

For example, the area of the region (hereinafter, called a dummy region) in which the circuit and wiring is not formed within one first semiconductor chip 10 may be small to accommodate the number of the through vias 15 desired to connect the first interposer 200 and the second interposer 300. When the plurality of first semiconductor chips 10 are provided between the first interposer 200 and the second interposer 300 according to some embodiments, the through via 15 may be dispersedly formed by using a dummy region of each of the plurality of first semiconductor chips 10.

The semiconductor package 2000 according to some embodiments of FIG. 3 and FIG. 4 may have the same effects as the semiconductor package 1000 according to some embodiments of FIG. 1 and FIG. 2. The semiconductor package 2000 according to some embodiments of FIG. 3 and FIG. 4 may include the plurality of first semiconductor chips 10 disposed between the first interposer 200 and the second interposer 300, and through vias configured to penetrate or extend into each of the plurality of first semiconductor chips 10 and connect the first interposer 200 and the second interposer 300. Additionally, according to the embodiment of FIG. 3 and FIG. 4, since the memories are controlled by a plurality of hosts, throughput of the semiconductor package 2000 per a same period may increase.

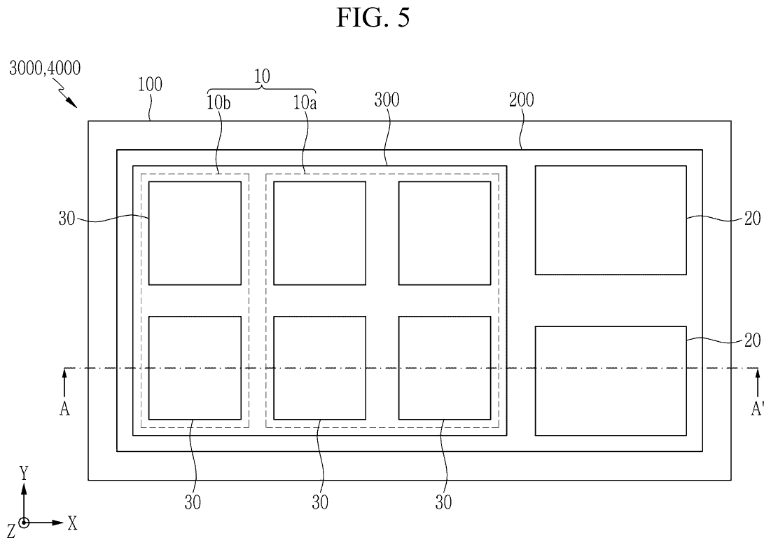

Hereinafter, referring to FIG. 5 to FIG. 7, various a semiconductor package according to some embodiments will be described.

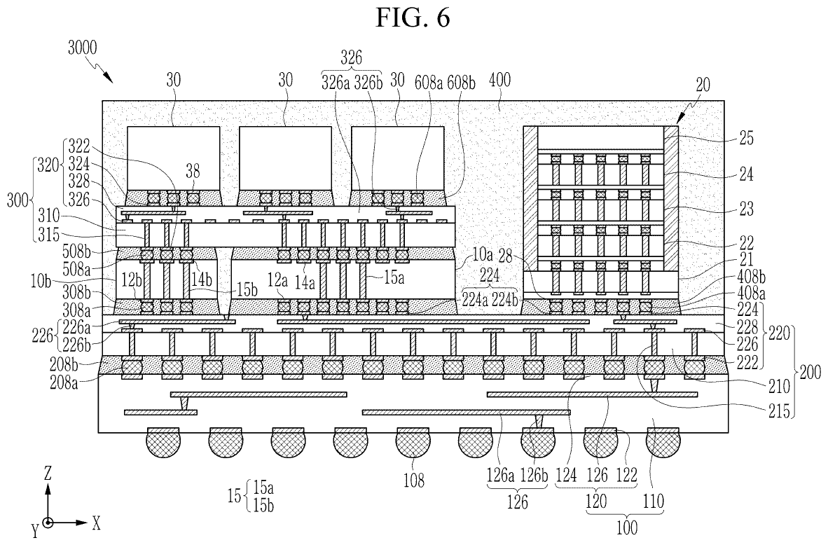

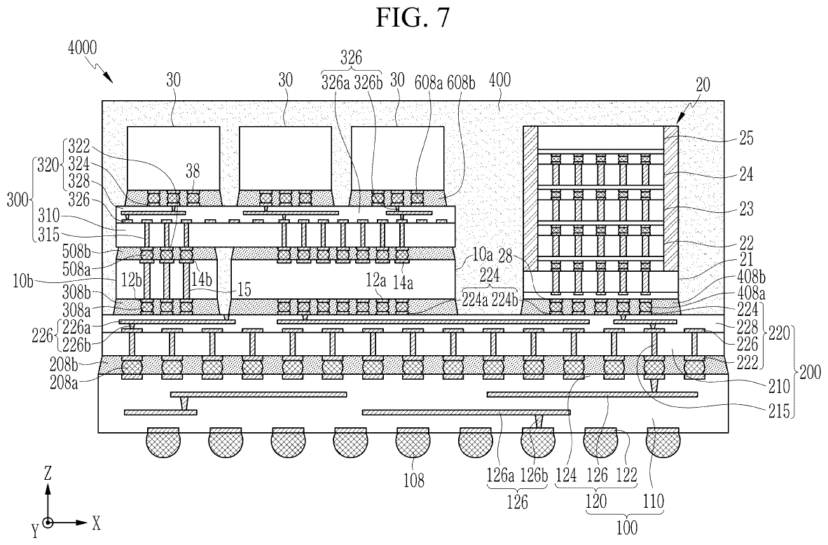

FIG. 5 is a top plan view of a semiconductor package 3000 or 4000 according to various embodiments. FIG. 6 is a cross-sectional view of a semiconductor package 3000 according to some embodiments taken along line A-A′ of FIG. 5. FIG. 7 is a cross-sectional view of a semiconductor package 4000 according to some embodiments taken along line A-A′ of FIG. 5. Hereinafter, as for the configurations in FIG. 5 to FIG. 7 referred to by the same reference symbol as the configurations of the semiconductor package 1000 of FIG. 1 and FIG. 2, the description described above with reference to FIG. 1 and FIG. 2 may be applied in the same or similar way. Therefore, redundant description may be omitted or simplified, and the semiconductor package 3000 of FIG. 5 and FIG. 6 and the semiconductor package 4000 and FIG. 5 and FIG. 7 will be described focusing on differences from the semiconductor package 1000 of FIG. 1 and FIG. 2.

According to some embodiments shown in FIG. 5 and FIG. 6, the semiconductor package 3000 may include the plurality of first semiconductor chips 10. The plurality of first semiconductor chips 10 may include a logic chip 10a and a dummy chip 10b. The logic chip 10a may include a circuit configured to generate and transfer a signal for controlling the second semiconductor chip 20 and/or the third semiconductor chip 30. The circuit of the logic chip 10a may include, for example, a transistor and a wiring connected to thereto. The dummy chip 10b may not separately include a circuit configured to generate and transfer signal for controlling the second semiconductor chip 20 and/or the third semiconductor chip 30.

The logic chip 10a and the dummy chip 10b may be disposed to be spaced apart from each other in the direction parallel to the upper surface of the package substrate 100. For example, the logic chip 10a and the dummy chip 10b may be disposed to be spaced apart in the X direction. The logic chip 10a and the dummy chip 10b may be disposed side by side in the X direction. Each of the logic chip 10a and the dummy chip 10b may overlap at least a portion of the at least one third semiconductor chip 30 in the Z direction and/or in a plan view. Referring to FIG. 5, it is illustrated that in a plan view, the size or area of the logic chip 10a is greater than the size or area of the dummy chip 10b, but embodiment is not limited thereto. The arrangement form of the logic chip 10a and the dummy chip 10b and the size of each of the logic chip 10a and the dummy chip 10b may be changed in various ways. FIG. 5 illustrates one logic chip 10a and one dummy chip 10b, but it is not limited thereto, and the number of each of the logic chip 10a and the dummy chip 10b may be changed in various ways.

In some embodiments, the logic chip 10a and the dummy chip 10b may be disposed between the first interposer 200 and the second interposer 300. Each of the logic chip 10a and the dummy chip 10b may be connected to the first interposer 200 and the second interposer 300, respectively. A logic chip upper pad 14a may be disposed on a logic chip lower pad 12a may be disposed on a lower surface of the logic chip 10a, and on an upper surface of the logic chip 10a. A dummy chip lower pad 12b may be disposed on a lower surface of the dummy chip 10b, and a dummy chip upper pad 14b may be disposed on an upper surface of the dummy chip 10b. The logic chip lower pad 12a and the dummy chip lower pad 12b may be connected to the first upper pad 224 (e.g., the first pad 224a) of the first interposer 200 by the first connection member 308a. The logic chip upper pad 14a and the dummy chip upper pad 14b may be connected to the second lower pad 322 of the second interposer 300 by the second interposer connection member 508a.

The logic chip 10a may include a circuit for controlling the memory and a wiring for signal transmission within the circuit or signal transmission between the circuit and the memory. The dummy chip 10b may not include a circuit for controlling the memory and wiring for the same. The dummy chip 10b may include a semiconductor material (e.g., silicon). The dummy chip 10b may only include through-silicon vias for connecting the first interposer 200 and a third interposer 300 and wires connected thereto.

The logic chip 10a may be electrically connected to the second semiconductor chip 20 through the first interposer 200. For example, the plurality of second semiconductor chips 20 may be connected to the first interposer 200. The logic chip 10a may be electrically connected to at least one of the plurality of second semiconductor chips 20. Each of the plurality of second semiconductor chips 20 may be electrically connected to the logic chip 10a.

The logic chip 10a may be electrically connected to the third semiconductor chip 30 through the second interposer 300. In some embodiments, the plurality of third semiconductor chips 30 may be connected to the second interposer 300, respectively. The logic chip 10a may be electrically connected to at least one of the plurality of third semiconductor chips 30. Each of the plurality of third semiconductor chips 30 may be electrically connected to the logic chip 10a.

In some embodiments, the through via 15 may include a first through via 15a penetrating or extending into the logic chip 10a and a second through via 15b penetrating or extending into the dummy chip 10b. The first through via 15a may connect the logic chip lower pad 12a and the logic chip upper pad 14a of the logic chip 10a. The second through via 15b may connect the dummy chip lower pad 12b and the dummy chip upper pad 14b of the dummy chip 10b. According to what is described above, the logic chip lower pad 12a and the dummy chip lower pad 12b may be connected to the first interposer 200, and the logic chip upper pad 14a and the dummy chip upper pad 14b may be connected to the second interposer 300. Each of the first through via 15a and the second through via 15b may connect the first interposer 200 and the second interposer 300. By the first through via 15a and the second through via 15b, the signal transmission path between the plurality of third semiconductor chips 30 and the first semiconductor chip 10, the second semiconductor chip 20, and/or the package substrate 100 may be optimized.

For example, the area of the region (hereinafter, called a dummy region) in which the circuit and wiring is not formed within the logic chip 10a may be small to accommodate the number of the through vias 15 desired to connect the first interposer 200 and the second interposer 300. When the dummy chip 10b in addition to the logic chip 10a is further provided between the first interposer 200 and the second interposer 300 according to some embodiments, the through via 15 may be dispersedly formed by using the dummy chip 10b. The dummy chip 10b may be added to secure the penetration region of the through via 15 without electrically affecting the semiconductor package 3000.

The semiconductor package 3000 according to some embodiments of FIG. 5 and FIG. 6 may have the same effects as the semiconductor package 1000 according to some embodiments of FIG. 1 and FIG. 2. The semiconductor package 3000 according to some embodiments of FIG. 5 and FIG. 6 may include the logic chip 10a and the dummy chip 10b disposed between the first interposer 200 and the second interposer 300, the first through via 15a penetrating or extending into the logic chip 10a, and the second through via 15b penetrating or extending into the dummy chip 10b. Additionally, according to the embodiment of FIG. 5 and FIG. 6, an additional space to form the through via 15 may be secured, to correspond to the size or area of the dummy chip 10b.

Hereinafter, the embodiment shown in FIG. 5 and FIG. 7 will be described focusing on the differences from the embodiment shown in FIG. 5 and FIG. 6.

According to some embodiments shown in FIG. 5 and FIG. 7, the semiconductor package 4000 may include the plurality of first semiconductor chips 10, and the plurality of first semiconductor chips 10 may include the logic chip 10a and the dummy chip 10b. The through via 15 may penetrate or extend into the dummy chip 10b. The through via 15 may not penetrate or extend into the logic chip 10a. At this time, one of the logic chip upper pad 14a or the logic chip lower pad 12a of the logic chip 10a may be omitted.

The through via 15 may connect the dummy chip lower pad 12b and the dummy chip upper pad 14b of the dummy chip 10b. According to what is described above, the dummy chip lower pad 12b may be connected to the first interposer 200, and the dummy chip upper pad 14b may be connected to the second interposer 300. The through via 15 may connect the first interposer 200 and the second interposer 300. By the through via 15 penetrating or extending into the dummy chip 10b and the dummy chip 10b, the signal transmission path between the plurality of third semiconductor chips 30 and the first semiconductor chip 10, the second semiconductor chip 20, and/or the package substrate 100 may be optimized.

For example, the area of the region (hereinafter, called a dummy region) in which the circuit and wiring is not formed within the logic chip 10a may be small to accommodate the through via 15 for connecting the first interposer 200 and the second interposer 300. When the dummy chip 10b in addition to the logic chip 10a is further provided between the first interposer 200 and the second interposer 300 according to some embodiments, the through via 15 may be formed by using the dummy chip 10b. The dummy chip 10b may be added to secure the penetration region of the through via 15 without electrically affecting the semiconductor package 1000.

The semiconductor package 4000 according to some embodiments of FIG. 5 and FIG. 7 may have the same effects as the semiconductor package 1000 according to some embodiments of FIG. 1 and FIG. 2. The semiconductor package 4000 according to some embodiments of FIG. 5 and FIG. 7 may include the logic chip 10a and the dummy chip 10b disposed between the first interposer 200 and the second interposer 300, and the through via 15 penetrating or extending into the dummy chip 10b. Additionally, according to the embodiment of FIG. 5 and FIG. 7, a space for forming the through via 15 connecting a first interposer 200 and the second interposer 300 may be secured by using the dummy chip 10b, and scaling of the size of the logic chip 10a that is not penetrated or extended into by the through via 15 may be possible.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package, comprising:
a package substrate;
a first interposer on the package substrate;
a first semiconductor chip and a second semiconductor chip that are on the first interposer;
a second interposer on the first semiconductor chip;
a third semiconductor chip on the second interposer; and
a first through via that extends into the first semiconductor chip and is between the first interposer and the second interposer.

2. The semiconductor package of claim 1, further comprising a plurality of third semiconductor chips that comprise the third semiconductor chip, wherein the plurality of third semiconductor chips are on the second interposer and are spaced apart from each other in a first direction that is parallel to an upper surface of the package substrate.

3. The semiconductor package of claim 2, wherein:
the second semiconductor chip is spaced apart from the first semiconductor chip in the first direction; and
the plurality of third semiconductor chips are spaced apart from the first semiconductor chip in a second direction that is perpendicular to the upper surface of the package substrate.

4. The semiconductor package of claim 2, further comprising a plurality of first semiconductor chips that comprise the first semiconductor chip, wherein the plurality of first semiconductor chips are between the first interposer and the second interposer.

5. The semiconductor package of claim 4, wherein each of the plurality of first semiconductor chips comprises a logic chip.

6. The semiconductor package of claim 5, further comprising a plurality of through vias that comprise the first through via, wherein the plurality of through vias respectively extend into each of the plurality of first semiconductor chips.

7. The semiconductor package of claim 4, wherein the plurality of first semiconductor chips comprises a logic chip and a dummy chip.

8. The semiconductor package of claim 7, further comprising a second through via that extends into the dummy chip, wherein the first through via extends into the logic chip.

9. The semiconductor package of claim 7, wherein the first through via only extends into the dummy chip.

10. The semiconductor package of claim 1, wherein:
the first semiconductor chip comprises a logic chip; and
the second semiconductor chip and the third semiconductor chip comprise memory chips.

11. A semiconductor package, comprising:
a package substrate;
a first interposer and a second interposer that are on an upper surface of the package substrate and are spaced apart from each other in a first direction that is perpendicular to an upper surface of the package substrate;
a first semiconductor chip that is between an upper surface of the first interposer and a lower surface of the second interposer;
a second semiconductor chip that is on the upper surface of the first interposer and is spaced apart from a side surface of the first semiconductor chip in a second direction that is parallel to the upper surface of the package substrate;
a plurality of third semiconductor chips that are on an upper surface of the second interposer and are spaced apart from each other in the second direction; and
a first through via that extends into the first semiconductor chip and is between the first interposer and the second interposer.

12. The semiconductor package of claim 11, further comprising a plurality of first semiconductor chips that comprise the first semiconductor chip, wherein the plurality of first semiconductor chips are between the upper surface of the first interposer and the lower surface of the second interposer.

13. The semiconductor package of claim 12, wherein:
each of the plurality of first semiconductor chips comprises a logic chip.

14. The semiconductor package of claim 12, further comprising a second through via, wherein:
the plurality of first semiconductor chips comprises a dummy chip;
the first semiconductor chip of the plurality of first semiconductor chips comprises a logic chip; and
the second through via extends into the dummy chip.

15. The semiconductor package of claim 12, wherein:
the plurality of first semiconductor chips comprises a logic chip; and
the first semiconductor chip of the plurality of first semiconductor chips comprises a dummy chip.

16. The semiconductor package of claim 11, wherein the first semiconductor chip is a logic chip, and the second semiconductor chip and the plurality of third semiconductor chips are memory chips.

17. The semiconductor package of claim 16, wherein the second semiconductor chip comprises a plurality of memory chips that are stacked in the first direction.

18. The semiconductor package of claim 11, wherein the first interposer comprises:
a first interposer substrate;
a plurality of first interposer-through vias that extend into the first interposer substrate; and
a first wiring portion on the first interposer substrate,
wherein the first wiring portion and the plurality of first interposer-through vias connect the first semiconductor chip, the second semiconductor chip, and the package substrate to each other.

19. The semiconductor package of claim 18, wherein the second interposer comprises:
a second interposer substrate;
a plurality of second interposer-through vias that extend into the second interposer substrate; and
a second wiring portion on the second interposer substrate,
wherein the second wiring portion and the plurality of second interposer-through vias electrically connect the plurality of third semiconductor chips to the first semiconductor chip and/or electrically connect the plurality of third semiconductor chips to each other.

20. A semiconductor package, comprising:
a package substrate;
an external connection member on a lower surface of the package substrate;
a first interposer on an upper surface of the package substrate;
a first interposer connection member that is between an upper surface of the package substrate and a lower surface of the first interposer;
a first semiconductor chip and a second semiconductor chip that are on an upper surface of the first interposer and are spaced apart from each other in a first direction that is parallel to an upper surface of the package substrate;
a first connection member that is between the upper surface of the first interposer and a lower surface of the first semiconductor chip;
a second connection member that is between the upper surface of the first interposer and a lower surface of the second semiconductor chip;
a second interposer on an upper surface of the first semiconductor chip;
a second interposer connection member that is between an upper surface of the first semiconductor chip and a lower surface of the second interposer;
a plurality of third semiconductor chips that are on an upper surface of the second interposer and are spaced apart from each other in the first direction;
a third connection member that is between the upper surface of the second interposer and a lower surface of each of the plurality of third semiconductor chips;
a molding member on the upper surface of the first interposer, the first interposer connection member, the first semiconductor chip, the second semiconductor chip, the first connection member, the second connection member, the second interposer, the second interposer connection member, the plurality of third semiconductor chips, and the third connection member; and
a through via that extends into the first semiconductor chip and physically connects the first interposer and the second interposer.
